(19) United States
(12) Patent Application Publication
(10) Pub. No.: US 2024/0204123 A1
(43) Pub. Date: Jun. 20, 2024

(54) HETEROJUNCTION CELL AND PROCESSING METHOD THEREFOR, AND BATTERY ASSEMBLY

(71) Applicant: RISEN ENERGY CO., LTD., Ningbo (CN)

(72) Inventors: Houmin CAI, Ningbo (CN); Yafeng LIU, Ningbo (CN); Xiao HUANG, Ningbo (CN); Jianming HU, Ningbo (CN); Lingxiang ZHANG, Ningbo (CN)

(21) Appl. No.: 18/419,599

(22) Filed: Jan. 23, 2024

Related U.S. Application Data
(63) Continuation of application No. PCT/CN2022/085058, filed on Apr. 2, 2022.

(30) Foreign Application Priority Data
Aug. 16, 2021 (CN) 202110937779.X

(51) Int. Cl. H01L 31/05; H01L 31/0224; H01L 31/0747; H01L 31/18

(52) U.S. Cl. CPC H01L 31/0504; H01L 31/186; H01L 31/022475; H01L 31/0747

(57) ABSTRACT

A heterojunction cell and a processing method thereof, and a battery assembly are provided. The heterojunction cell includes a substrate, a TCO film layer is provided on both a front surface and a back surface of the substrate, and at least two columns of short main gates with the same number are disposed at intervals on the TCO film layer of both the front surface and the back surface of the substrate, the short main gates located on the front surface of the substrate are defined as first main gates; the short main gates located on the back surface of the substrate are defined as second main gates; and the substrate is capable of being cut to form battery slices, each of the battery slices is provided with one column of the first main gates and one column of the second main gates.

### CROSS-REFERENCE TO RELATED APPLICATIONS

This application is a continuation of international patent application No. PCT/CN2022/085058, filed on Apr. 2, 2022, which itself claims priority to Chinese patent application No. 202110937779.X, filed on Aug. 16, 2021, and titled “HETEROJUNCTION CELL AND PROCESSING METHOD THEREFOR, AND BATTERY ASSEMBLY”. The content of the above identified application is hereby incorporated herein in their entireties by reference.

### TECHNICAL FIELD

The present disclosure relates to a field of a photovoltaic, and in particular, to a heterojunction cell and a processing method of the heterojunction cell, and a battery assembly.

### BACKGROUND

Policies have been issued to vigorously promote the development of photovoltaic industry to ease the energy crisis. In the last decade or so, with a rapid increase of a module power, various high-efficiency battery and module technologies have been applied rapidly.

At present, a highest industrialization efficiency of Passivated Emitter and Rear cell (PERC) is about 24.6%, while a highest industrialization efficiency of heterojunction solar cell and Tunnel Oxide Passivating Contacts solar cell (TOPCON) is 26.1% and 25.7% respectively. Coupled with advantages of heterojunction battery, such as high double-sided rate, low temperature coefficient, less production steps and high production yield, high-efficiency heterojunction battery module is undoubtedly important for the development of photovoltaic industry.

Currently, most solar cells on a market have main grids and fine grids on a front side and a back side, which are arranged in a grid-like way, and the main grids and the fine grids use silver paste as raw materials, which leads to a high consumption of the silver paste, thus increasing a battery cost.

### SUMMARY

According to various embodiments of the present disclosure, a heterojunction cell and a processing method therefor, and a battery assembly are provided.

The present disclosure provides a heterojunction cell. The heterojunction cell includes a substrate, the substrate is provided with a front surface and a back surface, a TCO film layer is provided on both the front surface and the back surface of the substrate (TCO: Transparent Conductive Oxide), and at least two columns of short main gates with the same number are disposed at intervals on the TCO film layer of both the front surface and the back surface of the substrate. The at least two columns of short main gates located on a side of the substrate adjacent to the front surface of the substrate are defined as first main gates, the at least two columns of short main gates located on a side of the substrate adjacent to the back surface of the substrate are defined as second main gates.

The substrate is capable of being cut to form at least two battery slices, each of the at least two battery slices includes two long edges opposite to each other and two short edges opposite to each other.

Each of the at least two battery slices is provided with one column of the first main gates and one column of the second main gates, wherein the one column of the first main gates is arranged adjacent to one of the two long edges of each of the at least two battery slices, and the one column of the second main gates is arranged adjacent to the other of the two long edges of each of the at least two battery slices.

In some embodiments, each of the at least two columns of short main gates is perpendicular to the two long edges of each of the at least two battery slices.

In some embodiments, a size of each of the at least two columns of short main gates along a direction of the two short edges of each of the at least two battery slices is in a range of 0.3 mm to 1.5 mm.

In some embodiments, the number of the second main gates is the same as the number of the first main gates, the second main gates correspond to the first main gates respectively one by one, and a projection of each of the second main gates on the front surface of the substrate and a projection of corresponding one of the first main gates on the front surface of the substrate is in the same line, which is perpendicular to the long edges of each of the at least two battery slices.

In some embodiments, the number of short main gates in each column of the at least two columns of short main gates is in a range 4 to 25.

In some embodiments, the substrate is in a square shape or a square shape with chamfers on four edges.

The present disclosure further provides a processing method of a heterojunction cell including following steps:
providing a substrate, the substrate is provided with a front surface and a back surface, and a TCO film layer is provided on both the front surface and the back surface of the substrate;
,disposing at least two columns of short main gates with the same number at intervals on the TCO film layer of both the front surface and the back surface of the substrate by printing, wherein the at least two columns of short main gates located on a side of the substrate adjacent to the front surface of the substrate are defined as first main gates, the at least two columns of short main gates located on a side of the substrate adjacent to the back surface of the substrate are defined as second main gates;
cutting the substrate into at least two battery slices, each of the at least two battery slices comprises two long edges opposite to each other and two short edges opposite to each other,
wherein each of the at least two battery slices is provided with one column of the first main gates and one column of the second main gates, wherein the one column of the first main gates is arranged adjacent to one of the two long edges of each of the at least two battery slices, and the one column of the second main gates is arranged adjacent to the other of the two long edges of each of the at least two battery slices.

The present disclosure further provides a battery assembly including a plurality of cells and a plurality of welding tapes. The plurality of cells are battery slices formed by cutting a heterojunction cell. Two ends of each of the plurality of welding tapes are respectively connected with the one column of the first main gates of one of adjacent two of the at least two battery slices and the one column of the second main gates of the other one of adjacent two of the at least two battery slices to connect the plurality of cells in series.

Details of one or more embodiments of this application are presented in the attached drawings and descriptions below. And other features, purposes and advantages of this application will become apparent from the description, drawings and claims.

### BRIEF DESCRIPTION OF THE DRAWINGS

For a better description and illustration of embodiments and/or examples of those disclosures disclosed herein, reference may be made to one or more attached drawings. Additional details or examples used to describe the drawings should not be considered as limiting the scope of any of the disclosed disclosures, currently described embodiments and/or examples, and currently understood best modes of these disclosures.

FIG. 1 is a sectional view of a heterojunction cell according to one embodiment.

FIG. 2 is a front view of a heterojunction cell according to one embodiment.

FIG. 3 is a rear view of a heterojunction cell in FIG. 2.

FIG. 4 is a front view of a battery slice according to one embodiment.

FIG. 5 is a rear view of a battery slice in FIG. 4.

FIG. 6 is a front view of a heterojunction cell according to another embodiment.

FIG. 7 is a rear view of a heterojunction cell in FIG. 6.

FIG. 8 is a sectional view of a battery assembly according to one embodiment.

FIG. 9 is a schematic view of the other side of a battery assembly in FIG. 8.

FIG. 10 is a partial sectional view of a battery assembly in FIG. 8.

In the figures, 1 represents a heterojunction cell; 10 represents a substrate; 101 represents a front surface; 102 represents a back surface; 10′ represents a battery slice; 103 represents a long edge; 104 represents a short edge; 20 represents a TCO film layer; 11 represents a N-type monocrystalline silicon layer; 12 represents an intrinsic amorphous silicon layer; 13 represents a P-type amorphous silicon layer; 30 represents a short main gate; 31 represents a first main gate; 32 represents a second main gate; 40 represents a welding tape; 50 represents a cell; 60 represents a conductive adhesive; 90 represents a center line; 91 represents a first trisecting line; and 92 represents a second trisecting line.

### DETAILED DESCRIPTION

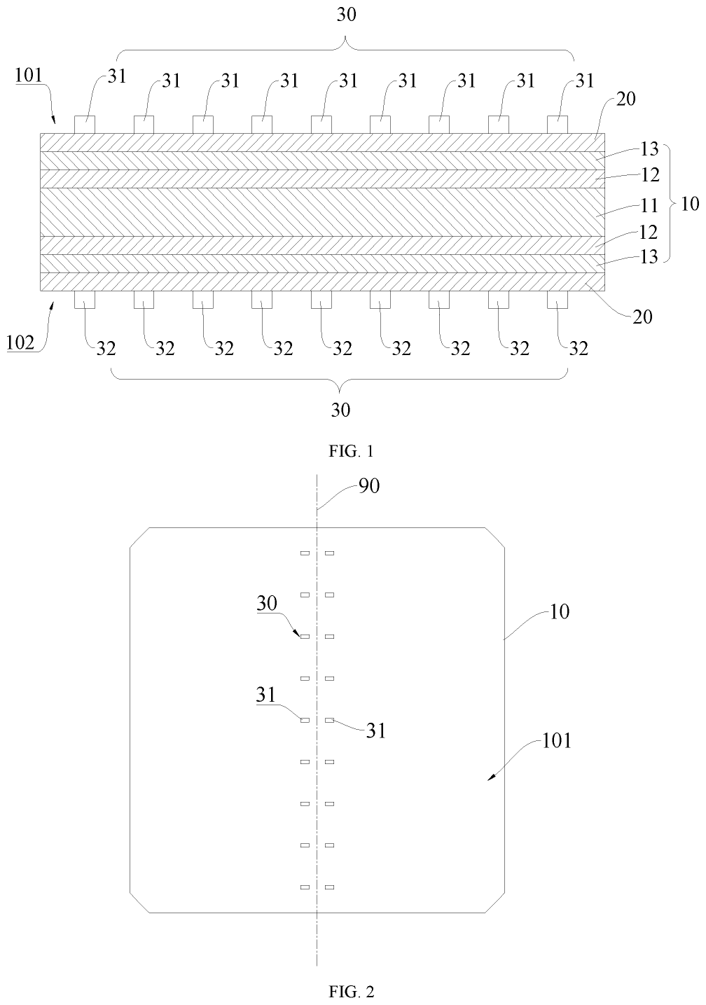

Referring to FIG. 1 to FIG. 3, the present disclosure provides a heterojunction cell. The heterojunction cell includes a substrate 10, the substrate 10 with a front surface 101 and a back surface 102. A TCO film layer 20 is provided on both the front surface 101 and the back surface 102 of the substrate, and at least two columns of short main gates 30 with same number are disposed at intervals on the TCO film layer 20 of both the front surface 101 and the back surface 102 of the substrate 10. The at least two columns of short main gates 30 located on a side of the substrate 10 adjacent to the front surface 101 of the substrate 10 are defined as first main gates 31, the at least two columns of short main gates 30 located on a side of the substrate 10 adjacent to the back surface 102 of the substrate 10 is defined as second main gates 32. In other words, the short main gates 30 includes a plurality of first main gates 31 located on the front surface 101 of the substrate 10 and a plurality of second main gates 32 located on the back surface 102 of the substrate 10.

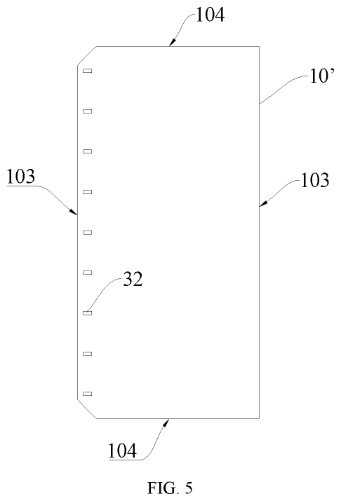

Referring to FIG. 4 to FIG. 5, the substrate 10 is capable of being cut to form at least two battery slices 10′, each of the at least two battery slices 10′ includes two long edges 103 opposite to each other and two short edges 104 opposite to each other.

Each of the at least two battery slices 10′ is provided with one column of the first main gates 31 and one column of the second main gates 32. The one column of the first main gates 31 is arranged adjacent to one of the two long edges 103 of each of the at least two battery slices 10′, and the one column of the second main gates 104 is arranged adjacent to the other of the two long edges 103 of each of the at least two battery slices 10′. In this way, it is convenient to connect the first main gates 31 of one battery slice 10′ with the second main gates 32 of adjacent battery slice 10′ by a welding tape, thus facilitating a confluence transmission of charge carriers.

In the heterojunction cell provided by the present disclosure, since the front surface 101 and the back surface 102 of the substrate 10 are both provided with the TCO film layer 20 and the TCO film layer 20 has greater conductivity, the charge carriers can be collected through the TCO film layer 20. Thereby, the charge carriers can be collected in the short main gate 30 and then transmitted by the welding tape 40.

In the related art, main grids and fine grids are arranged on a front surface and a back surface of a battery slice, a projection of each of the main grids of the front surface on the battery slice and projections of corresponding one of the main grids of the back surface on the battery slice overlap, and the fine grids are vertically connected with the main grids and form a grid-like structure, which leads to more consumption of silver paste. However, the heterojunction cell in the present disclosure is only provided with the short main gates 30, omitting the fine grids, the short main gates 30 includes the first main gates 31 and the second main gates 32, a projection of each of the second main gates 32 on the front surface 101 of the substrate 10 does not overlap with a projection of corresponding one of the first main gates 31 on the front surface 101 of the substrate 10, and the first main gates 31 and the second main gates 32 are respectively arranged adjacent to the long edges 103 of the battery slice 10′, which greatly reduces a consumption of the silver paste, thus reducing a cost.

The substrate 10 is a basic element of the heterojunction cell, which realizes unidirectional conduction by forming a p-n junction. Referring to FIG. 1, in an embodiment, the substrate 10 includes a n-type monocrystal silicon layer 11, an intrinsic amorphous silicon layer 12 arranged on both sides of the n-type monocrystal silicon layer 11, and a p-type amorphous silicon layer 13 arranged on a surface of each of the intrinsic amorphous silicon layers 12. The TCO film layer 20 is disposed on a surface of each of the p-type amorphous silicon layers 13.

The TCO film layer 20 is a conductive film layer, which can collect the charge carriers and assemble them into the short main gate 30. Moreover, the TCO film layer 20 is made of a transparent material which will not affect an irradiation of light on the substrate 10. It can be seen that, by replacing the fine grid with the TCO film layer 20 and the short main gates 30 and reducing a length of the main grids, it can not only ensure a normal electrical performance of the cell 50, but also reduce an amount of silver pastes.

In this embodiment, the short main gates 30 are perpendicular to the long edge 103 of the battery slice 10′, that is, the first main gates 31 and the second main gates 32 are perpendicular to the long edges 103 of the battery slice 10′. “The short main gates 30 are perpendicular to the long edges 103 of the battery slice 10′” means that the short main gates 30 are perpendicular to the long edges 103 of the battery slice 10′, but it does not mean that the short main gates 30 is connected to the long edges 103 of the battery slice 10′. The short main gates 30 May be connected to one of the long edges 103 of the battery slice 10′, or it may not be connected to the two long edges 103 of the battery slice 10′. As mentioned above, the first main gates 31 are located adjacent to one of the two long edges 103 of the battery slice 10′, and the second main gates 32 are located adjacent to the other one of the two long edges 103 of the battery slice 10′. In this embodiment, the first main gates 31 are arranged adjacent to one of the two long edges 103 of the battery slice 10′ and extend toward the other one of the two long edges 103 of the battery slice 10′, that is, the first main gates 31 are parallel to the short edge 104 of the battery slice 10′. Similarly, the second main gates 32 are arranged adjacent to the other of the two long edges 103 of the battery slice 10′ and extend towards the long edge 103 of the battery slice 10′ where the first main gates 31 is arranged, that is, the second main gates 32 are parallel to the short edge 104 of the battery slice 10′.

Referring to FIG. 4, a length of the short main gate 30 along a direction of the short edge 104 is defined as L, and the length L of the short main gate 30 is in a range of 0.3 mm to 1.5 mm, so that the short main gates 30 have enough length to connect with the welding tape 40, ensuring both a reliability of the connection between the cell 50 and the welding tape 40 and a collection and a transmission of the charge carriers, and decreasing a consumption of the silver paste and greatly reducing the cost. Specifically, the length L of the short main gates 30 can be 0.3 mm, 0.4 mm, 0.5 mm, 0.6 mm, 0.7 mm, 0.8 mm, 0.9 mm, 1.0 mm, 1.1 mm, 1.2 mm, 1.3 mm, 1.4 mm, 1.5 mm, and so on, which are not listed here.

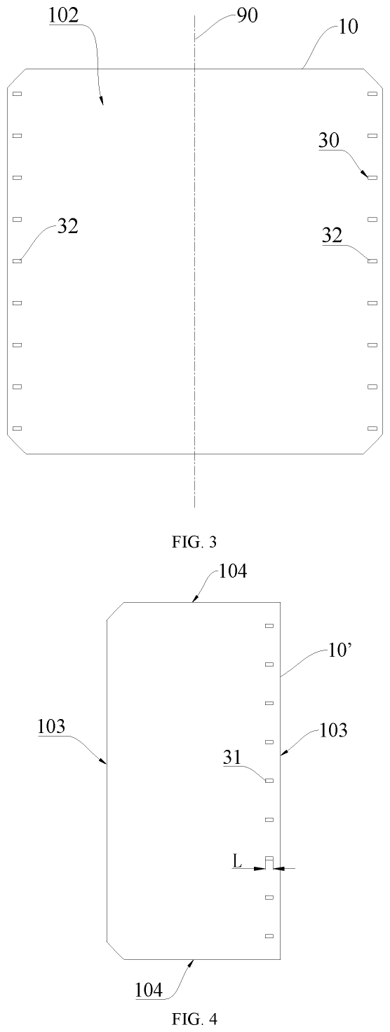

Referring to FIG. 2 and FIG. 3, in an embodiment, the number of the second main gates 32 is the same as the number of the first main gates 31, and the second main gates 32 correspond to the first main gates 31 respectively one by one. A projection of each of the second main gates 32 on the front surface 101 of the substrate 10 and a projection of corresponding one of the first main gates 31 on the front surface 101 of the substrate 10 is in the same line, which is perpendicular to the long edges 103 of each of the at least two battery slices 10′. In this way, the first main gates 31 and the second main gates 32 can be conveniently connected through the welding tape 40, so that a plurality of the battery slices 10′ can be connected in series to form a battery assembly, and the connection of the welding tape 40 facilitates a transmission of the charge carriers. A projection of each of the second main gates 32 on the front surface 101 of the substrate 10 and a projection of corresponding one of the first main gates 31 on the front surface 101 of the substrate 10 is in the same line, which is perpendicular to the long edges 103 of each of the at least two battery slices 10′, thus the short edges 104 of the battery slices 10′ after series connection is in the same straight line.

The number of the short main gates 30 in each column is in a range of 4 to 25, in this way, efficient collection of the charge carriers on the TCO film layer 20 can be ensured. Referring to FIG. 2, the number of the short main gates 30 in each column is 9. Of course, in other embodiments, the number of the short main gates 30 in each column can also be 4, 5, 6, 7, 8, 10, 11, 12, 13, 14, 15, 16, 17, 18, 19, 20, 21, 22, 23, 24, and 25.

The substrate 10 is in a square shape or a square shape with chamfers on four edges. The substrate 10 is capable of being cut to form a battery slice 10′ with a rectangular shape, and the battery slice 10′ can be connected in series through the welding tape 40.

The substrate 10 is provided with two opposite first edges and two opposite second edges, the first edge corresponds to the long edge 103 of the battery slice 10′ and the second edge corresponds to the short edge 104 of the battery slice 10′.

Referring to FIG. 2 and FIG. 3, in this embodiment, the heterojunction cell can be cut to form two pieces of the battery slices 10′ (i.e., two slices). Specifically, the first main gates 31 are arranged in two columns, the two columns of the first main gates 31 are arranged adjacent to a center line 90 of the second edge of the substrate 10, and the two columns of the first main gate 31 are respectively located on both sides of the center line 90 of the second side of the substrate 10. The second main gates 32 is also arranged in two columns, and the two columns of the second main gates 32 are respectively arranged adjacent to the two first edges of the substrate 10. In this way, when the substrate 10 is cut along the center line 90 of the second side of the substrate 10, the heterojunction cell is cut into two pieces of the battery slices 10′. Referring to FIG. 4 to FIG. 5, each of the two pieces of the battery slices 10′ is provided with one column of the first main gates 31 and one column of the second main gates 32. The one column of the first main gates 31 is located adjacent to a long edge 103 of one of two pieces of the battery slices 10′, and the one column of the second main gates 32 is located adjacent to a long edge 103 of the other of two pieces of the battery slices 10′. By connecting the first main gates 31 of one battery slice 10′ and the second main gate 32 of adjacent battery slice 10′ through the welding tape 40, a plurality of the battery slices 10′ can be connected in series to form the battery assembly. In this way, the battery assembly can collect more of the charge carriers and generate more electricity.

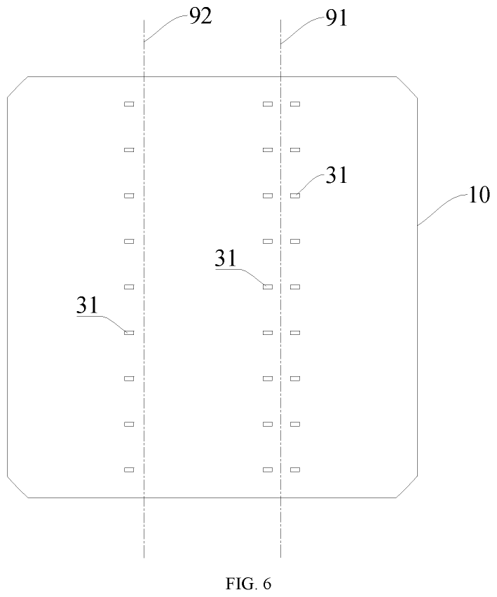

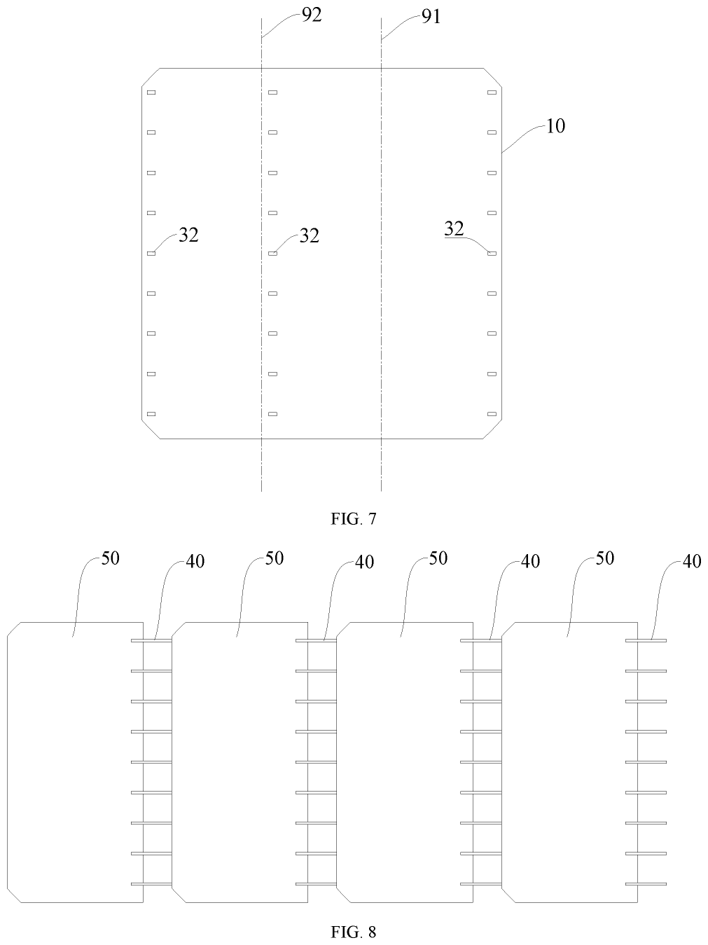

Referring to FIG. 6 to FIG. 7, in this embodiment, the heterojunction cell can be cut to form three pieces of the battery slices 10′ (i.e., three slices). Specifically, two trisecting line of the second edge of the substrate 10 are a first trisecting line 91 and a second trisecting line 92, respectively. The first main gates 31 is arranged in three columns, wherein two columns of the first main gates 31 are arranged adjacent to the first trisecting line 91, and the two columns of the first main gates 31 are located on both sides of the first trisecting line 91. The other column of the first main gates 31 is located adjacent to the second trisecting line 92 and on a side of the second trisecting line 92 away from the first trisecting line 91. The second main gates 32 are arranged in three columns, wherein two columns of the second main gates 32 are arranged adjacent to two first sides of the substrate 10, the other column of the second main gates 32 is located adjacent to the second trisecting line 92 and on a side of the second trisecting line 92 adjacent to the first trisecting line 91. In this way, by cutting the substrate 10 along the two trisecting line on the second side of the substrate 10, the heterojunction cell can be cut into three battery slices. Each of the battery slices 10′ is provided with one column of the first main gates 31 and one column of the second main gates 32. The first main gate 31 is located adjacent to a long edge 103 of one battery slice 10′, and the second main gate 32 is located adjacent to the long edges 103 of adjacent battery slice 10′. By connecting the first main gate 31 of one battery slice 10′ and the second main gate 32 of adjacent battery slice 10′ through the welding tape 40, a plurality of the battery slices 10′ can be connected in series to form the battery assembly. In this way, the battery assembly can collect more of the charge carriers and generate more electricity.

The example of cutting the heterojunction cell in two cuts or three cuts is listed above. Similarly, the heterojunction cell can also be cut in four slices, five slices, six slices, seven slices, eight slices, nine slices, ten slices and so on. As long as each of the battery slices 10′ obtained after cutting is provided with one column of the first main gates 31 and one column of the second main gates 32. The situations of four slices, five slices, six slices, seven slices, eight slices, nine slices and ten slices will not be described in detail.

The present disclosure further provides a processing method of a heterojunction cell including following steps:
providing a substrate 10, the substrate 10 is provided with a front surface 101 and a back surface 102, and a TCO film layer 20 is provided on both the front surface 101 and the back surface 102 of the substrate 10;
disposing at least two columns of short main gates 30 with the same number at intervals on the TCO film layers 20 of both the front surface 101 and the back surface 102 of the substrate 10 by printing, wherein the at least two columns of short main gates 30 located on a side of the substrate 10 adjacent to the front surface 101 of the substrate 10 are defined as first main gates 31, the at least two columns of short main gates 30 located on a side of the substrate 10 adjacent to the back surface 102 of the substrate 10 are defined as second main gates 32; and
cutting the substrate 10 into at least two battery slices 10′, each of the at least two battery slices 10′ includes two long edges 103 opposite to each other and two short edges 104 opposite to each other;
wherein each of the at least two battery slice 10′ is provided with one column of the first main gates 31 and one column of the second main gates 32, wherein the one column of the first main gates 31 is arranged adjacent to one of the two long edges 103 of each of the at least two battery slices 10′, and the one column of the second main gates 32 is arranged adjacent to the other of the two long edge 103 of each of the at least two battery slices 10′.

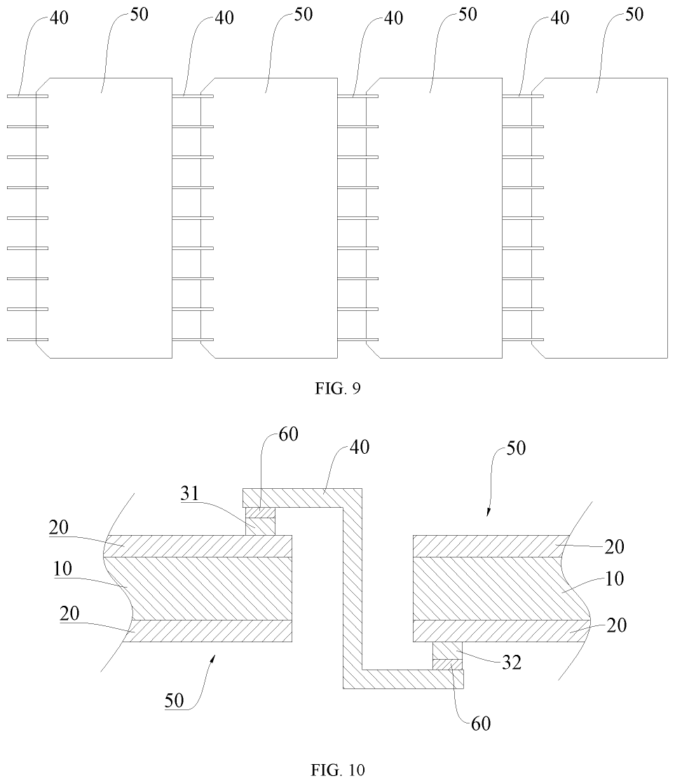

Referring to FIG. 8 to FIG. 10, the present disclosure further provides a battery assembly including a plurality of cells 50 and a plurality of welding tapes 40, the plurality of cells 50 are battery slices 10′ formed by cutting a heterojunction cell described in the above embodiments. Two ends of each of the plurality of welding tapes 40 are respectively connected with the one column of the first main gates 31 of one of adjacent two cells 50 and the one column of the second main gates 32 of the other one of adjacent two cells 50 to connect the plurality of cells 50 in series. The battery assembly realizes the series connection of the plurality of cells 50 through the plurality of welding tapes 40, so that the charge carriers are collected through the TCO film layer 20 and assembled into the first main gate 31 and the second main gate 32, and transmitted through the plurality of welding tapes 40.

In an embodiment, the welding tape 40 and the short main gate 30 are connected by a conductive adhesive 60, that is, the welding tape 40 and the first main gate 31 are connected by the conductive adhesive 60, and the welding tape 40 and the second main gate 32 are also connected by the conductive adhesive 60. The conductive adhesive 60 has certain elasticity, the welding tape 40 is connected to the short main gate 30 through the conductive adhesive 60, which can reduce a stress on the cell 50 caused by the connection of the welding tape 40 and reduce a fragment rate of the cell 50, thereby ensuring a connection firmness between the welding tape 40 and the cell 50, and ensuring a reliability of the battery assembly. Of course, in other embodiment, the welding tape 40 and the short main gate 30 can also be directly and fixedly connected, for example, by welding, which is not specifically described in the present disclosure.

Furthermore, the present disclosure further provides a packaging method of a battery assembly including following steps: S1, coating a conductive adhesive 60 on both ends of a welding tape 40, wherein the conductive adhesive 60 is respectively located on both sides of the welding tape 40, parts of the welding tape 40 coated with the conductive adhesive 60 are respectively connected to and in contact with the first main gate 31 of a cell 50 and the second main gate 32 of adjacent cell 50; and, S2, heating and pressurizing a contact part of the welding tape 40 and the cell 50 to cure the conductive adhesive 60. The battery assembly has a simple structure and a simple packaging method. The welding tape 40 and the cell 50 are connected by the conductive adhesive 60, which has greater connection strength and will not cause concentrated stress, greatly reducing a fragment rate and ensuring a reliability and a quality of the battery assembly.

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the present disclosure.

One of ordinary skill in the art should recognize that the above embodiments are used only to illustrate the present disclosure and are not used to limit the present disclosure, and that appropriate variations and improvements to the above embodiments fall within the protection scope of the present disclosure so long as they are made without departing from the substantial spirit of the present disclosure.

What is claimed is:

1. A heterojunction cell, comprising a substrate, wherein the substrate is provided with a front surface and a back surface, a TCO film layer is provided on both the front surface and the back surface of the substrate, and at least two columns of short main gates with the same number are disposed at intervals on the TCO film layer of both the front surface and the back surface of the substrate;
the at least two columns of short main gates located on a side of the substrate adjacent to the front surface of the substrate are defined as first main gates, the at least two columns of short main gates located on a side of the substrate adjacent to the back surface of the substrate are defined as second main gates, and
wherein the substrate is capable of being cut to form at least two battery slices, each of the at least two battery slices comprises two long edges opposite to each other and two short edges opposite to each other; each of the at least two battery slices is provided with one column of the first main gates and one column of the second main gates, wherein the one column of the first main gates is arranged adjacent to one of the two long edges of each of the at least two battery slices, and the one column of the second main gates is arranged adjacent to the other of the two long edges of each of the at least two battery slices.

2. The heterojunction cell of claim 1, wherein each of the at least two columns of short main gates is perpendicular to the two long edges of each of the at least two battery slices.

3. The heterojunction cell of claim 1, wherein a size of each of the at least two columns of short main gates along a direction of the two short edges of each of the at least two battery slices is in a range of 0.3 mm to 1.5 mm.

4. The heterojunction cell of claim 1, wherein the number of the second main gates is the same as the number of the first main gates, the second main gates correspond to the first main gates respectively one by one, and a projection of each of the second main gates on the front surface of the substrate and a projection of corresponding one of the first main gates on the front surface of the substrate is in the same line, which is perpendicular to the long edges of each of the at least two battery slices.

5. The heterojunction cell of claim 1, wherein the number of short main gates in each of the at least two columns of short main gates is in a range 4 to 25.

6. The heterojunction cell of claim 3, wherein the substrate is in a square shape or a square shape with chamfers on four edges.

7. A processing method of a heterojunction cell, comprising following steps:
providing a substrate, wherein the substrate is provided with a front surface and a back surface, and a TCO film layer is provided on both the front surface and the back surface of the substrate;
disposing at least two columns of short main gates with the same number at intervals on the TCO film layer of both the front surface and the back surface of the substrate by printing, wherein the at least two columns of short main gates located on a side of the substrate adjacent to the front surface of the substrate are defined as first main gates, the at least two columns of short main gates located on a side of the substrate adjacent to the back surface of the substrate are defined as second main gates; and
cutting the substrate into at least two battery slices, each of the at least two battery slices comprises two long edges opposite to each other and two short edges opposite to each other, wherein each of the at least two battery slices is provided with one column of the first main gates and one column of the second main gates, wherein the one column of the first main gates is arranged adjacent to one of the two long edges of each of the at least two battery slices, and the one column of the second main gates is arranged adjacent to the other of the two long edges of each of the at least two battery slices.

8. A battery assembly, comprising a plurality of cells and a plurality of welding tapes, wherein the plurality of cells are battery slices formed by cutting a heterojunction cell, wherein the heterojunction cell comprises a substrate, the substrate is provided with a front surface and a back surface, a TCO film layer is provided on both the front surface and the back surface of the substrate, and at least two columns of short main gates with the same number are disposed at intervals on the TCO film layer of both the front surface and the back surface of the substrate;
the at least two columns of short main gates located on a side of the substrate adjacent to the front surface of the substrate are defined as first main gates, the at least two columns of short main gates located on a side of the substrate adjacent to the back surface of the substrate are defined as second main gates; the substrate is cut to form at least two battery slices, each of the at least two battery slices comprises two long edges opposite to each other and two short edges opposite to each other;
each of the at least two battery slices is provided with one column of the first main gates and one column of the second main gates, wherein the one column of the first main gates is arranged adjacent to one of the two long edges of each of the at least two battery slices, and the one column of the second main gates is arranged adjacent to the other of the two long edges of each of the at least two battery slices;
two ends of each of the plurality of welding tapes are respectively connected with the one column of the first main gates of one of adjacent two of the at least two battery slices and the one column of the second main gates of the other of adjacent two of the at least two battery slices to connect the plurality of cells in series.

9. The battery assembly of claim 8, wherein two ends of each of the plurality of welding tapes are respectively connected with the one column of the first main gates of one of adjacent two of the at least two battery slices and the one column of the second main gates of the other one of adjacent two of the at least two battery slices by a conductive adhesive.

10. The battery assembly of claim 8, wherein two ends of each of the plurality of welding tapes are directly and fixedly connected with both the one column of the first main gates of one of adjacent two of the at least two battery slices and the one column of the second main gates of the other one of adjacent two of the at least two battery slices.

11. The battery assembly of claim 8, wherein each of the at least two columns of short main gates is perpendicular to the two long edges of each of the at least two battery slices.

12. The battery assembly of claim 8, wherein a size of each of the at least two columns of short main gates along a direction of the two short edges of each of the at least two battery slices is in a range of 0.3 mm to 1.5 mm.

13. The battery assembly of claim 8, wherein the number of the second main gates is the same as the number of the first main gates, the second main gates correspond to the first main gates respectively one by one, and a projection of each of the second main gates on the front surface of the substrate and a projection of corresponding one of the first main gates on the front surface of the substrate is in the same line, which is perpendicular to the long edges of each of the at least two battery slices.

14. The battery assembly of claim 8, wherein the number of short main gates in each column of the at least two columns of short main gates is in a range 4 to 25.

15. The battery assembly of claim 8, wherein the substrate is in a square shape or a square shape with chamfers on four edges.
